(19) United States
(12) Patent Application Publication
(10) Pub. No.: US 2025/0126981 A1
(43) Pub. Date: Apr. 17, 2025

(54) DISPLAY DEVICE AND METHOD OF FABRICATING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/762,198

(22) Filed: Jul. 2, 2024

(30) Foreign Application Priority Data
Oct. 11, 2023 (KR) 10-2023-0134904

(51) Int. Cl. H10K 59/122; H10K 59/12

(52) U.S. Cl. CPC H10K 59/122; H10K 59/1201

(57) ABSTRACT

A display device includes a substrate including an emission area and a non-emission area; an anode electrode on the emission area of the substrate; a pixel defining layer on the non-emission area of the substrate and defining an opening; a light emitting layer on the anode electrode; a common electron layer on the light emitting layer and the pixel defining layer; and a common electrode on the common electron layer, the pixel defining layer includes a first portion overlapping the non-emission area; and a second portion overlapping the emission area and spaced apart from the first portion in a direction parallel to the substrate with a groove therebetween, the groove being recessed toward the substrate, the light emitting layer contacts the first portion and the second portion, and the light emitting layer fills the groove between the first portion and the second portion.

### CROSS-REFERENCE TO RELATED APPLICATION(S)

This application claims priority to and benefits of Korean Patent Application No. 10-2023-0134904 under 35 U.S.C. 119 filed on Oct. 11, 2023 in the Korean Intellectual Property Office, the entire contents of which are incorporated herein by reference.

### BACKGROUND

### 1. Technical Field

The disclosure relates to a display device and a method of fabricating the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel may include light emitting elements that may emit light by themselves.

Recently, as various electronic devices develop, the demand for high-resolution display devices has increased. Since the high-resolution display device requires a high degree of integration of pixels, an interval between light emitting elements overlapping respective emission areas may be reduced. Accordingly, the high-resolution display device may be formed by a photolithography process of forming individual pixels rather than a mask process.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of solving detachment defects of light emitting layers in forming a plurality of pixels by a photolithography process, and a method of fabricating the same.

However, aspects of the disclosure are not restricted to those set forth herein. The above and other aspects of the disclosure will become more apparent to one of ordinary skill in the art to which the disclosure pertains by referencing the detailed description of the disclosure given below.

An embodiment of a display device may include a substrate including an emission area and a non-emission area; an anode electrode disposed on the emission area of the substrate; a pixel defining layer disposed on the non-emission area of the substrate, the pixel defining layer defining an opening; a light emitting layer disposed on the anode electrode; a common electron layer disposed on the light emitting layer and the pixel defining layer; and a common electrode disposed on the common electron layer, wherein the pixel defining layer may include a first portion overlapping the non-emission area; and a second portion overlapping the emission area and spaced apart from the first portion in a direction parallel to the substrate with a groove disposed between the first portion and the second portion, the groove being recessed toward the substrate, the light emitting layer may contact the first portion and the second portion, and the light emitting layer fills the groove between the first portion and the second portion.

A height of the pixel defining layer in a direction perpendicular to the substrate may be less than about half the height of the light emitting layer.

The second portion may be completely surrounded by the anode electrode and the light emitting layer.

The pixel defining layer may include an inorganic material, and the first portion and the second portion include a same material.

The opening may be completely surrounded by the emission area in plan view.

The common electron layer may be disposed between the pixel defining layer and the common electrode in a portion overlapping the non-emission area.

The common electron layer may contact the first portion and the common electrode in the portion overlapping the non-emission area.

A side surface of the light emitting layer facing the non-emission area may contact the common electron layer.

The light emitting layer may be formed by photolithography.

The second portion may include a plurality of grooves recessed in a direction toward the substrate.

The light emitting layer may fill the plurality of grooves included in the second portion.

An embodiment of a display device may include a substrate including an emission area and a non-emission area; an anode electrode disposed on the emission area of the substrate; a pixel defining layer including a first portion disposed on the non-emission area of the substrate and a second portion including a different material from the first portion, the second portion disposed on the first portion; a light emitting layer disposed on the anode electrode; a common electron layer disposed on the light emitting layer and the pixel defining layer; and a common electrode disposed on the common electron layer, wherein a side surface of the second portion facing the emission area protrudes toward the emission area more than a side surface of the first portion facing the emission area, and an undercut may be formed between the second portion and the side surface of the first portion in a portion overlapping the emission area.

The light emitting layer may fill the undercut formed between the second portion and the side surface of the first portion.

A height of the first portion in a direction perpendicular to the substrate may be greater than a height of the second portion.

The pixel defining layer may further include a third portion disposed on the second portion, the third portion and the first portion including a same material; and a fourth portion disposed on the third portion, the fourth portion and the second portion including a same material, and a side surface of the fourth portion protrudes toward the emission area more than a side surface of the third portion in the portion overlapping the emission area.

An undercut may be formed between the fourth portion and the side surface of the third portion in the portion overlapping the emission area, and the light emitting layer fills the undercut formed between the fourth portion and the side surface of the third portion.

A width of the undercut formed between the first portion and the second portion and a width of the undercut formed between the third portion and the fourth portion in a direction parallel to the substrate may be about 0.05 μm or less.

The first portion and the third portion may include either silicon nitride or silicon oxynitride, and the second portion and the fourth portion include silicon oxide.

The common electron layer may be disposed between the fourth portion and the common electrode in a portion overlapping the non-emission area, and the common electron layer contacts the fourth portion and the common electrode in the portion overlapping the non-emission area.

An embodiment of a method of fabricating a display device may include providing a substrate including an emission area and a non-emission area; forming a first anode electrode and a second anode electrode spaced apart from each other on the emission area of the substrate and forming a pixel defining material layer completely covering the first anode electrode, the second anode electrode, and the substrate; forming a pixel defining layer including first portions and second portions spaced apart from the first portions with each of grooves disposed between the first portions and the second portions by removing portions of the pixel defining material layer except for portions overlapping the non-emission area and a portion of the emission area through etching, the grooves being recessed toward the substrate; forming a first light emitting layer by forming a first light emitting material layer completely covering the first anode electrode, the second anode electrode, and the pixel defining layer, entirely forming a sacrificial layer on the first light emitting material layer, and removing the first light emitting material layer and the sacrificial layer in a remaining portion excluding a portion overlapping the first anode electrode through etching; forming a second light emitting layer by forming a second light emitting material layer completely covering the first light emitting layer, the second anode electrode, and the pixel defining layer, entirely forming a sacrificial layer on the second light emitting material layer, and removing the second light emitting material layer and the sacrificial layer except for a portion overlapping the second anode electrode through etching; and removing the sacrificial layer using wet etching, forming a common electron layer completely covering the first light emitting layer, the second light emitting layer, and the pixel defining layer, and entirely forming a common electrode on the common electron layer, wherein in the forming of the first light emitting layer and the forming of the second emitting layer, the first light emitting layer and the second light emitting layer may fill the grooves disposed between the first portions and the second portions of the pixel defining layer.

Detailed contents of other embodiments are described in a detailed description and are illustrated in the drawings.

In a display device according to an embodiment, it is possible to improve adhesive strength between a light emitting layer and an underlying structure by forming a plurality of pixels through photolithography and forming a pixel defining layer including a single groove or a plurality of groove between the plurality of pixels. Accordingly, the display device according to an embodiment may solve a detachment defect of the light emitting layer. It is possible to provide a display device applicable to ultra-high resolution by forming the plurality of pixels through the photolithography process.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating an electronic device according to an embodiment;

FIG. 2 is a schematic perspective view illustrating a display device included in the electronic device;

FIG. 3 is a schematic cross-sectional view of the display device of FIG. 2;

FIG. 4 is a schematic plan view of a display layer in FIG. 3;

FIG. 5 is a schematic plan view illustrating an arrangement of emission areas in a display area of FIG. 4;

FIG. 6 is a schematic cross-sectional view of the display area taken along line X1-X1′ of FIG. 5;

FIG. 7 is an enlarged cross-sectional view of a light emitting element in FIG. 6;

FIG. 8 is an enlarged cross-sectional view of a first emission area in FIG. 6;

FIG. 9 is an enlarged cross-sectional view of a first emission area according to an embodiment;

FIG. 10 is a schematic cross-sectional view of a display area taken along line X1-X1′ of FIG. 5;

FIG. 11 is an enlarged cross-sectional view of area ‘C’ in FIG. 10;

FIG. 12 is an enlarged cross-sectional view of area ‘P’ in FIG. 11; and

FIGS. 13 to 22 are schematic cross-sectional views illustrating a method of fabricating a display element layer in FIG. 6.

### DETAILED DESCRIPTION OF THE EMBODIMENTS

In the following description, for the purposes of explanation, numerous details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these details or with one or more equivalent arrangements. Here, various embodiments do not have to be exclusive nor limit the disclosure. For example, shapes, configurations, and characteristics of an embodiment may be used or implemented in another embodiment.

Unless otherwise specified, illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (for example, rotated (about) 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing embodiments and is not intended to be limiting.

As used herein, the singular forms, “a,” “an,” and “the” are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Furthermore, “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of embodiments may be physically separated into two or more interacting and discrete blocks, units, and/or modules without departing from the scope of the disclosure. Further, the blocks, units, and/or modules of embodiments may be physically combined into more complex blocks, units, and/or modules without departing from the scope of the disclosure.

Hereinafter, embodiments of the disclosure will be described in detail with reference to the accompanying drawings.

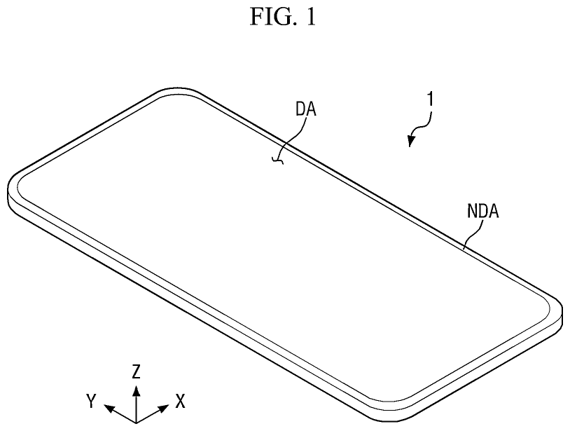

FIG. 1 is a schematic perspective view of an electronic device 1 according to an embodiment.

Referring to FIG. 1, the electronic device 1 displays a moving image or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be included in the electronic device 1.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a transverse direction in the drawings, the second direction (Y-axis direction) refers to a longitudinal direction in the drawings, and the third direction (Z-axis direction) refers to an upward and downward direction (for example, a thickness direction) in the drawings. In the following specification, unless otherwise specified, the term “direction” may refer to both directions toward both sides extending along the direction. In case that both “directions” extending to both sides need to be distinguished from each other, one side or a side will be referred to as “one side in the direction” and the other side or another side will be referred to as “the other side in the direction”. In FIG. 1, a direction to which an arrow indicating a direction is directed will be referred to as one side or a side, and a direction opposite to such a direction will be referred to as the other side or another side.

Hereinafter, for convenience of explanation, in referring to surfaces of the electronic device 1 or respective members constituting the electronic device 1, one surface or a surface facing one side or a side in a direction in which an image is displayed, for example, the third direction (Z-axis direction) will be referred to as an upper surface, and a surface opposite to the one surface will be referred to as the other surface or another surface. However, the disclosure is not limited thereto, and the one surface and the other surface of the member may be referred to as a front surface and a rear surface, respectively, or be referred to as a first surface and a second surface, respectively. In describing relative positions of the respective members of the electronic device 1, one side or a side in the third direction (Z-axis direction) may be referred to as an upper portion and the other side in the third direction (Z-axis direction) may be referred to as a lower portion.

A shape of the electronic device 1 may be variously modified. For example, the electronic device 1 may have a shape such as a rectangular shape with a width greater than a length, a rectangular shape with a length greater than a width, a square shape, a quadrangular shape with rounded corners (vertices), other polygonal shapes, or a circular shape.

The electronic device 1 may include a display area DA and a non-display area NDA. The display area DA is an area in which a screen may be displayed, and the non-display area NDA is an area in which the screen is not displayed. The display area DA may also be referred to as an active area, and the non-display area NDA may also be referred to as a non-active area. The display area DA may occupy substantially the center of the electronic device 1.

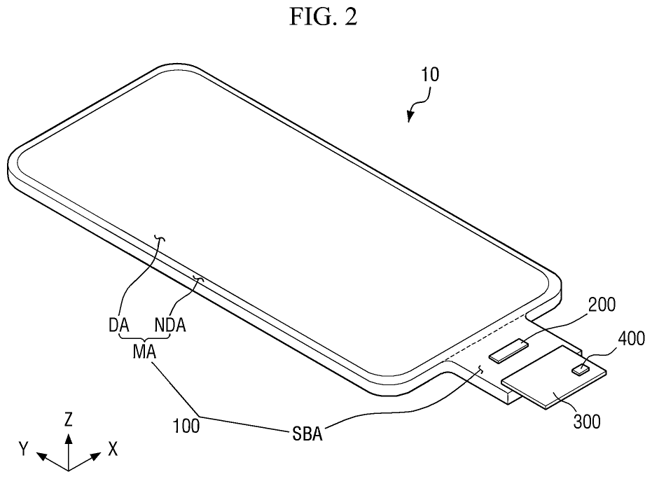

FIG. 2 is a schematic perspective view illustrating a display device 10 included in the electronic device 1 according to an embodiment.

Referring to FIG. 2, the electronic device 1 according to an embodiment may include a display device 10. The display device 10 may provide a screen displayed on the electronic device 1. Examples of the display device 10 may include an inorganic light emitting diode display device, an organic light emitting display device, a quantum dot light emitting display device, a plasma display panel, a field emission display, and the like within the spirit and the scope of the disclosure. Hereinafter, a case where an organic light emitting diode display device is applied as an example of the display device will be described by way of example, but the disclosure is not limited thereto, and the same technical spirit may be applied to other display devices as applicable.

The display device 10 may have a shape similar to that of the electronic device 1 in plan view. For example, the display device 10 may have a rectangular shape, in plan view, having short sides in the first direction (X-axis direction) and long sides in the second direction (Y-axis direction). A corner where the short side in the first direction (X-axis direction) and the long side in the second direction (Y-axis direction) meet may be rounded with a curvature, but is not limited thereto, and may also be right-angled. The shape of the display device 10 in plan view is not limited to the rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA disposed around the display area DA.

The display area DA may emit light from a plurality of emission areas or a plurality of opening areas to be described later. For example, the display panel 100 may include pixel circuits including switching elements, a pixel defining film defining the emission areas or the opening areas, and self-light emitting elements. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto. It has been illustrated in the drawings that the self-light emitting element is an organic light emitting diode.

The non-display area NDA may be an area outside the display area DA. The non-display area NDA may be defined as an edge area of the main area MA of the display panel 100.

The sub-area SBA may be an area extending from one side or a side of the main area MA. The sub-area SBA may include a flexible material that may be bent, folded, and rolled. For example, in case that the sub-area SBA is bent, the sub-area SBA may overlap the main area MA in a thickness direction (for example, the Z-axis direction). The sub-area SBA may include the display driver 200 and pad parts connected to the circuit board 300. In an embodiment, the sub-area SBA may be omitted, and the display driver 200 and the pad parts may be positioned in the non-display area NDA.

The display driver 200 may output signals and voltages for driving the display panel 100. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the pad parts of the display panel 100 using an anisotropic conductive film (ACF). The circuit board 300 may be a flexible printed circuit board, a printed circuit board, or a flexible film such as a chip on film.

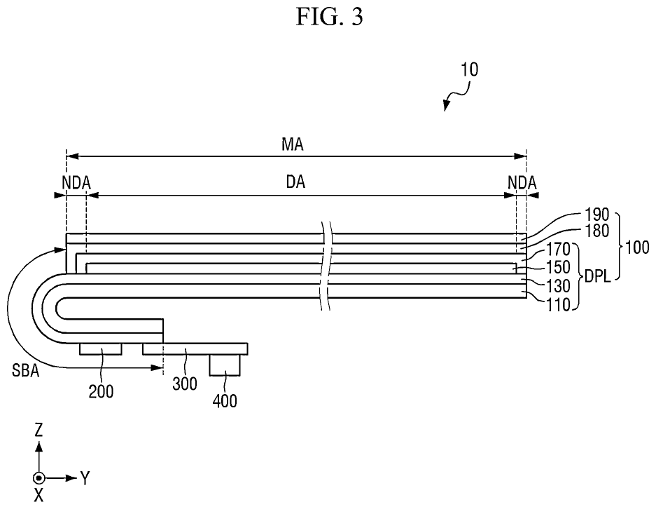

The touch driver 400 may be mounted on the circuit board 300. The touch driving circuit 400 may be connected to a touch sensor layer 180 (see FIG. 3) of the display panel 100. The touch driver 400 may be formed as an integrated circuit.

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, and rolled. For example, the substrate 110 may include a polymer resin such as polyimide (PI), but is not limited thereto. In an embodiment, the substrate 110 may include a glass material or a metal material.

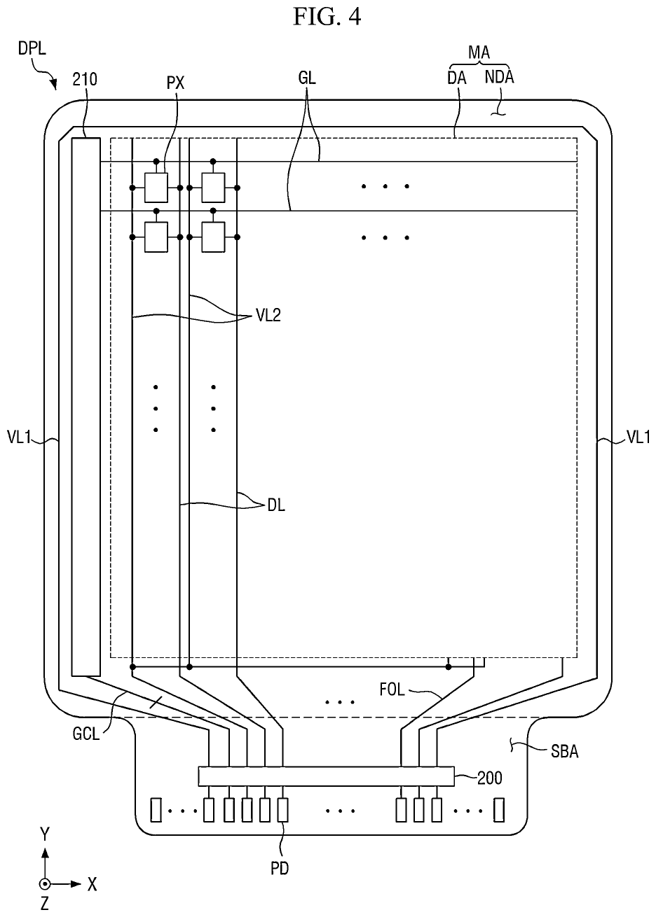

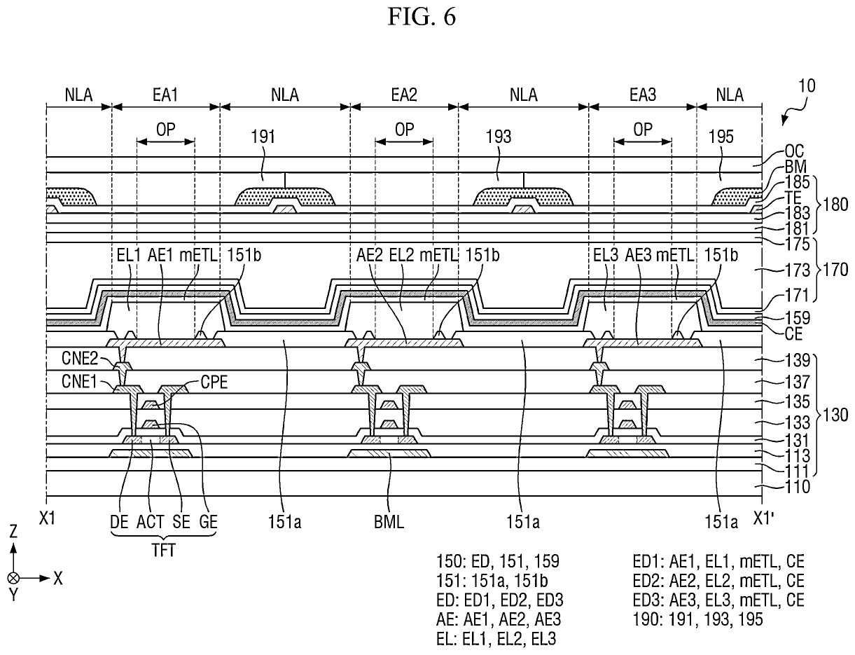

The thin film transistor layer 130 may be disposed on the substrate 110. The thin film transistor layer 130 may be disposed in the display area DA, the non-display area NDA, and the sub-area SBA. The thin film transistor layer 130 may include a plurality of thin film transistors TFT (see FIG. 6) constituting a pixel PX (see FIG. 4).

The display element layer 150 may be disposed on the thin film transistor layer 130. The display element layer 150 may be positioned to overlap the display area DA. The display element layer 150 may include a plurality of light emitting elements ED (see FIG. 6). As an example, the light emitting element according to an embodiment may include at least one of an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulation layer 170 may be positioned on the display element layer 150. The thin film encapsulation layer 170 may be positioned to overlap the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may be positioned to overlap the display area DA and the non-display area NDA. The touch sensor layer 180 may sense a user's touch in a mutual capacitance manner or a self-capacitance manner.

The color filter layer 190 may be disposed on the touch sensor layer 180. The color filter layer 190 may be positioned to overlap the display area DA and the non-display area NDA. The color filter layer 190 may absorb some of light introduced from the outside of the display device 10 to reduce reflected light by external light. Accordingly, the color filter layer 190 may prevent distortion of colors due to external light reflection.

Since the color filter layer 190 is directly disposed on the touch sensor layer 180, the display device 10 may not require a separate substrate for the color filter layer 190. Accordingly, a thickness of the display device 10 may be relatively small. The color filter layer 190 may also be omitted according to embodiments.

As illustrated in FIG. 3, a portion of the display layer DPL overlapping the sub-area SBA may be bent. In case that a portion of the display layer DPL is bent, the display driver 200, the circuit board 300, and the touch driver 400 may overlap the main area MA in the third direction (Z-axis direction).

FIG. 4 is a schematic plan view of a display layer DPL in FIG. 3.

Referring to FIG. 4, the display layer DPL included in an embodiment may include a plurality of pixels PX, a plurality of gate lines GL, a plurality of data lines DL, and a plurality of second power lines VL2 in a portion overlapping the display area DA of the main area MA.

Each of the plurality of pixels PX may be defined as a minimum unit emitting light. Each of the plurality of pixels PX may constitute each of first to third emission areas EA1, EA2, and EA3 to be described later.

The plurality of gate lines GL may supply gate signals received from a gate driver 210 to the plurality of pixels PX. The plurality of gate lines GL may extend in the first direction (X-axis direction), and may be spaced apart from each other in the second direction (Y-axis direction) intersecting the first direction (X-axis direction).

The plurality of data lines DL may supply data voltages received from the display driver 200 to the plurality of pixels PX. The plurality of data lines DL may extend in the second direction (Y-axis direction), and may be spaced apart from each other in the first direction (X-axis direction).

The plurality of second power lines VL2 may supply a source voltage received from the display driver 200 to the plurality of pixels PX. Here, the source voltage may be at least one of a driving voltage, an initialization voltage, and a reference voltage. The plurality of second power lines VL2 may extend in the second direction (Y-axis direction), and may be spaced apart from each other in the first direction (X-axis direction).

The display layer DPL included in an embodiment may include a first power line VL1, the gate driver 210, a plurality of fan-out lines FOL, and a gate control line GCL in a portion overlapping the non-display area NDA of the main area MA.

The gate driver 210 may generate a plurality of gate signals based on a gate control signal, and may sequentially supply the plurality of gate signals to the plurality of gate lines GL according to a set order.

The first power line VL1 may be disposed in the non-display area NDA so as to surround the display area DA. The first power line VL1 may supply a source voltage received from the display driver 200 to the plurality of pixels PX. The first power line VL1 may be electrically connected to various wiring lines positioned in the display area DA.

The plurality of fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210. It has been illustrated in FIG. 4 that the gate driver 210 is disposed only in a non-display area NDA disposed on the left side of the display area DA, but the disclosure is not limited thereto. In an embodiment, the display device 10 may include a plurality of gate drivers 210 respectively disposed on the left side and the right side of the display area DA.

The display layer DPL included in an embodiment may include the display driver 200 and a plurality of display pads PD in a portion overlapping the sub-area SBA.

The display driver 200 may output signals and voltages for driving the plurality of pixels PX to the plurality of fan-out lines FOL. The display driver 200 may supply the data voltages to the data lines DL through the plurality of fan-out lines FOL. As a result, the data voltages may be supplied to the plurality of pixels PX, and may control luminance of the plurality of pixels PX. The display driver 200 may supply the gate control signals to the gate driver 210 through the gate control lines GCL.

The plurality of display pads PD may be connected to a graphic system through the circuit board 300. The plurality of display pads PD may be connected to the circuit board 300 to receive digital video data, and may supply the digital video data to the display driver 200.

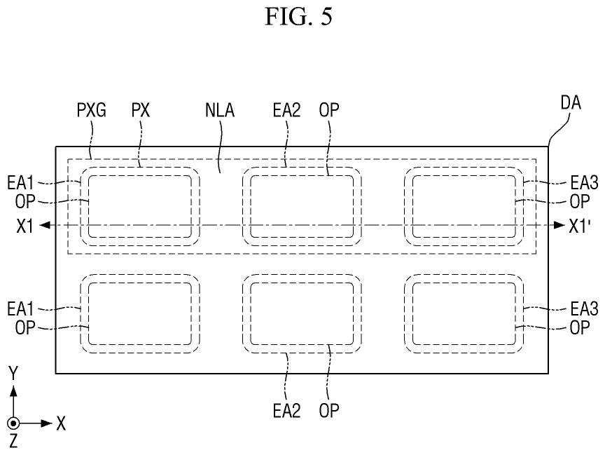

FIG. 5 is a schematic plan view illustrating an arrangement of emission areas in a display area DA of FIG. 4.

Referring to FIG. 5, the display area DA may include first to third emission areas EA1, EA2, and EA3 and a non-emission area NLA.

The non-emission area NLA may be positioned to surround each of the first to third emission areas EA1, EA2, and EA3. The non-emission area NLA may assist in preventing each light emitted from the first to third emission areas EA1, EA2, and EA3 from being mixed with each other. An inorganic pixel defining layer 151 (see FIG. 6) to be described later may be disposed in the non-emission area NLA. The inorganic pixel defining layer 151 may define openings OP. The openings OP defined by the inorganic pixel defining layer 151 may be disposed inside the first to third emission areas EA1, EA2, and EA3. In other words, the openings OP may be completely surrounded by the first to third emission areas EA1, EA2, and EA3 in plan view.

The plurality of pixels PX may include a first emission area EA1, a second emission area EA2, and a third emission area EA3 that emit light of different colors. The first to third emission areas EA1, EA2, and EA3 may emit red, green, or blue light, respectively, and colors of the light emitted from the first to third emission areas EA1, EA2, and EA3 may be different from each other depending on types of light emitting elements ED to be described later. In an embodiment, the first emission area EA1 may emit the red light, which is light of a first light, the second emission area EA2 may emit the green light, which is light of a second color, and the third emission area EA3 may emit the blue light, which is light of a third color, but the disclosure is not limited thereto.

It has been illustrated in FIG. 5 that sizes or areas of the first to third emission areas EA1, EA2, and EA3 are the same as each other, but the disclosure is not limited thereto. As an example, a size and an area of the first emission area EA1 may be the smallest, and a size and an area of the third emission area EA3 may be the greatest. By way of example, a size and an area of the first emission area EA1 may be the greatest, and a size and an area of the third emission area EA3 may be the smallest. For example, sizes, areas, and shapes of the first to third emission areas EA1, EA2, and EA3 may be freely adjusted according to required characteristics.

At least one first emission area EA1, at least one second emission area EA2, and at least one third emission area EA3 disposed adjacent to each other may constitute one pixel group PXG. The pixel group PXG may be a minimum unit emitting white light. However, types and/or the number of first to third emission areas EA1, EA2, and EA3 constituting the pixel group PXG may be changed according to embodiments.

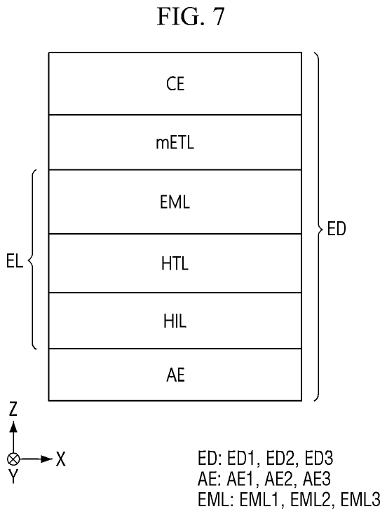

FIG. 6 is a schematic cross-sectional view of the display area DA taken along line X1-X1′ of FIG. 5. FIG. 7 is an enlarged cross-sectional view of a light emitting element ED in FIG. 6.

FIG. 6 is a schematic cross-sectional view of the display device 10 overlapping the display area DA, and illustrates cross sections of the substrate 110, the thin film transistor layer 130, the display element layer 150, the thin film encapsulation layer 170, the touch sensor layer 180, and the color filter layer 190. The substrate 110 has been described with reference to FIG. 3, and a description thereof will thus be omitted.

Referring to FIG. 6, the thin film transistor layer 130 may be positioned on the substrate 110. The thin film transistor layer 130 may include a first buffer layer 111, a bottom metal layer BML, a second buffer layer 113, thin film transistors TFT, a gate insulating layer 131, a first interlayer insulating layer 133, capacitor electrodes CPE, a second interlayer insulating layer 135, first connection electrodes CNE1, a first via layer 137, second connection electrodes CNE2, and a second via layer 139.

The first buffer layer 111 may be disposed on the substrate 110. The first buffer layer 111 may include an inorganic film capable of preventing permeation of air or moisture. For example, the first buffer layer 111 may include a plurality of inorganic films that may be alternately stacked each other.

The bottom metal layer BML may be disposed on the first buffer layer 111. For example, the bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second buffer layer 113 may cover the first buffer layer 111 and the bottom metal layer BML. The second buffer layer 113 may include an inorganic film capable of preventing permeation of air or moisture. For example, the second buffer layer 113 may include a plurality of inorganic films that may be alternately stacked each other.

The thin film transistor TFT may be disposed on the second buffer layer 113, and may constitute a pixel circuit connected to each of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the second buffer layer 113. The active layer ACT may overlap the bottom metal layer BML and the gate electrode GE in the thickness direction, and may be insulated from the gate electrode GE by the gate insulating layer 131. A material of the active layer ACT in portions of the active layer ACT may become conductors to form the source electrode SE and the drain electrode DE.

The gate electrode GE may be disposed on the gate insulating layer 131. The gate electrode GE may overlap the active layer ACT with the gate insulating layer 131 therebetween.

The gate insulating layer 131 may be disposed on the active layer ACT. For example, the gate insulating layer 131 may cover the active layer ACT and the second buffer layer 113, and may insulate the active layer ACT and the gate electrode GE from each other. The gate insulating layer 131 may include contact holes through which the first connection electrodes CNE1 penetrate.

The first interlayer insulating layer 133 may cover the gate electrodes GE and the gate insulating layer 131. The first interlayer insulating layer 131 may include contact holes through which the first connection electrodes CNE1 penetrate. The contact holes of the first interlayer insulating layer 133 may be connected to the contact holes of the gate insulating layer 131 and contact holes of the second interlayer insulating layer 135.

The capacitor electrodes CPE may be disposed on the first interlayer insulating layer 133. The capacitor electrode CPE may overlap the gate electrode GE in the thickness direction. The capacitor electrode CPE and the gate electrode GE may form capacitance.

The second interlayer insulating layer 135 may cover the capacitor electrodes CPE and the first interlayer insulating layer 133. The second interlayer insulating layer 135 may include contact holes through which the first connection electrodes CNE1 penetrate. The contact holes of the second interlayer insulating layer 135 may be connected to the contact holes of the first interlayer insulating layer 133 and the contact holes of the gate insulating layer 131.

The first connection electrodes CNE1 may be disposed on the second interlayer insulating layer 135. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer 135, the first interlayer insulating layer 133, and the gate insulating layer 131 to be in contact with the drain electrode DE of the thin film transistor TFT.

The first via layer 137 may cover the first connection electrodes CNE1 and the second interlayer insulating layer 135. The first via layer 137 may planarize an underlying structure. The first via layer 137 may include contact holes through which the second connection electrodes CNE2 penetrate.

The second connection electrodes CNE2 may be disposed on the first via layer 137. The second connection electrode CNE2 may electrically connect the first connection electrode CNE1 and an anode electrode AE to each other. The second connection electrode CNE2 may be inserted into the contact hole formed in the first via layer 137 to be in contact with the first connection electrode CNE1.

The second via layer 139 may cover the second connection electrodes CNE2 and the first via layer 137. The second via layer 139 may include contact holes through which the anode electrodes AE penetrate.

The display element layer 150 may be disposed on the thin film transistor layer 130. The display element layer 150 may include an inorganic pixel defining layer 151, a light emitting element ED, and a capping layer 159.

The inorganic pixel defining layer 151 may be disposed on the second via layer 139 in portions overlapping the non-emission area NLA, and may be disposed on first to third anode electrodes AE1, AE2, and AE3 in portions overlapping the emission areas EA1, EA2, and EA3. The inorganic pixel defining layer 151 may define the openings OP, and may expose portions of the anode electrodes AE in portions overlapping the openings OP. The inorganic pixel defining layer 151 may allow the first to third anode electrodes AE1, AE2, and AE3 from being spaced apart and insulated from each other.

The inorganic pixel defining layer 151 according to an embodiment may include first portions 151a and second portions 151b. The first portions 151a of the inorganic pixel defining layer 151 may be disposed in the portions overlapping the non-emission area NLA, and may be most of the inorganic pixel defining layer 151. The second portions 151b of the inorganic pixel defining layer 151 may be disposed in the portions overlapping the first to third emission areas EA1, EA2, and EA3, and may be disposed to be spaced apart from the first portions 151a in the first direction (X-axis direction).

The inorganic pixel defining layer 151 may include an inorganic insulating material. As an example, the inorganic pixel defining film 151 may include aluminum oxide, titanium oxide, tantalum oxide, hafnium oxide, zinc oxide, silicon oxide, silicon nitride, and silicon oxynitride.

The light emitting elements ED may include a first light emitting element ED1, a second light emitting element ED2, and a third light emitting element ED3 respectively overlapping the first to third emission areas EA1, EA2, and EA3. The first light emitting element ED1, the second light emitting element ED2, and the third light emitting element ED3 may emit light of different colors depending on materials included in light emitting layers EL. For example, the first light emitting element ED1 may emit red light, which is light of a first light, the second light emitting element ED2 may emit green light, which is light of a second color, and the third light emitting element ED3 may emit blue light, which is light of a third color.

Referring to FIGS. 6 and 7, the light emitting element ED may include an anode electrode AE, a light emitting layer EL, a common electron transporting layer mETL, and a common electrode CE. The light emitting layer EL may include a hole injection layer HIL, a hole transporting layer HTL, and an organic light emitting layer EML.

The anode electrode AE may be disposed on the second via layer 139. The anode electrode AE may include a first anode electrode AE1 overlapping the first emission area EA1, a second anode electrode AE2 overlapping the second emission area EA2, and a third anode electrode AE3 overlapping the third emission area EA3. The first anode electrode AE1, the second anode electrode AE2, and the third anode electrode AE3 may be disposed to be spaced apart from each other on the second via layer 139, respectively. As described above, the first anode electrode AE1, the second anode electrode AE2, and the third anode electrode AE3 may be spaced apart from each other by the inorganic pixel defining layer 151, and may be exposed in the portions overlapping the openings OP. The anode electrode AE may be electrically connected to the drain electrode DE of the thin film transistor TFT through the first connection electrode CNE1 and the second connection electrode CNE2.

In an embodiment, the anode electrode AE may have a stacked film structure in which a layer made of a material having a high work function, such as indium tin oxide (ITO), indium zinc oxide (IZO), zinc oxide (ZnO), or indium oxide (In₂O₃) and a layer made of a reflective material such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or mixtures thereof may be stacked. As an example, the anode electrode AE may have a multilayer structure of ITO/Mg, ITO/MgF, ITO/Ag, and ITO/Ag/ITO, but is not limited thereto.

The light emitting layer EL may be disposed on the anode electrode AE. In the display device 10 according to an embodiment, the light emitting layer EL may be formed by a photolithography process. Since the photolithography process forms the light emitting layer EL without a mask, a high-resolution product in which an interval between the plurality of pixels PX neighboring to each other is narrow may be readily fabricated. A fabricating process will be described later.

The light emitting layer EL may include a first light emitting layer EL1, a second light emitting layer EL2, and a third light emitting layer EL3 respectively disposed in the first to third emission areas EA1, EA2, and EA3. The first light emitting layer EL1, the second light emitting layer EL2, and the third light emitting layer EL3 may emit light of different colors depending on a material included in an organic light emitting layer EML to be described later. As an example, the first light emitting layer EL1 may emit the red light, which is the light of the first color, the second light emitting layer EL2 may emit the green light, which is the light of the second color, and the third light emitting layer EL3 may emit the blue light, which is the light of the third color, but the disclosure is not limited thereto.

The light emitting layer EL may include the hole injection layer HIL, the hole transporting layer HTL, and the organic light emitting layer EML. The hole injection layer HIL may be positioned on the anode electrode AE, the hole transporting layer HTL may be positioned on the hole injection layer HIL, and the organic light emitting layer EML may be positioned on the hole transporting layer HTL. According to embodiments, the hole injection layer HIL and the hole transporting layer HTL may be formed as a hole injection transporting layer, which is one layer.

The hole injection layer HIL may have a single layer made of a single material, a single layer made of a plurality of different materials, or a multilayer structure including a plurality of layers each made of different materials. As an example, the hole injection layer HIL may include a phthalocyanine compound such as copper phthalocyanine, N,N′-diphenylN,N′-bis-[4-(phenyl-m-tolyl-amino)-phenyl]-biphenyl-4,4′-diamine (DNTPD), 4,4′,4″-tris(3methylphenylphenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), or the like, but is not limited thereto.

The hole transporting layer HTL may have a single layer made of a single material, a single layer made of a plurality of different materials, or a multilayer structure including a plurality of layers each made of different materials. As an example, the hole transporting layer HTL may include a carbazole-based derivative such as N-phenylcarbazole and polyvinylcarbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (CTA), N,N′-di (1-naphthyl)-N,N′-diphenylbenzidine (NPB), 4,4′-cyclohexylidene bis[N,N-bis(4-methylphenyl)benzenamine] (TAPC), or the like, but is not limited thereto.

The organic light emitting layer EML may include a first organic light emitting layer EML1, a second organic light emitting layer EML2, and a third organic light emitting layer EML3 respectively overlapping the first to third emission areas EA1, EA2, and EA3. The organic light emitting layer EML may include a host material and a dopant material. The first organic light emitting layer EML1, the second organic light emitting layer EML2, and the third organic light emitting layer EML3 may emit the light of the different colors by using a phosphorescent or fluorescent material as a dopant in addition to the host material and combining the host material and the dopant material with each other.

The host material is not particularly limited as long as it is a commonly used material, but may be, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2″-dimethyl-biphenyl (CDBP), 2-methyl-9,10-bis(naphthalen-2-yl)anthracene (MADN), or the like within the spirit and the scope of the disclosure.

As an example, in case that the first organic light emitting layer EML1 emits the red light, the first organic light emitting layer EML1 may include a fluorescent material including perylene or tris(dibenzoylmethanato)phenanthoroline europium (PBD:Eu(DBM)3(phen)). In this case, the dopant material included in the first organic light emitting layer EML1 may be selected from, for example, a metal complex or an organometallic complex such as bis(1-phenylquinoline)acetylacetonate iridium (PIQIr(acac)), bis(1-phenylquinoline)acetylacetonateiridium (PQIr(acac)), tris(1-phenylquinoline)iridium (PQIr), and octaethylporphyrin platinum (PtOEP).

As an example, in case that the second organic light emitting layer EML2 emits the green light, the second organic light emitting layer EML2 may include a fluorescent material including tris(8-hydroxyquinolino)aluminum (Alq3). In this case, the dopant material included in the second organic light emitting layer EML2 may be selected from, for example, a metal complex or an organometallic complex such as fac-tris(2-phenylpyridine)iridium (Ir(ppy)3).

As an example, in case that the third organic light emitting layer EML3 emits the blue light, the third organic light emitting layer EML3 may include a fluorescent material including any one selected from the group consisting of spiro-DPVBi, spiro-6P, distyryl-benzene (DSB), distyryl-arylene (DSA), a polyfluorene (PFO)-based polymer, and a poly(p-phenylene vinylene) (PPV)-based polymer. In this case, the dopant material included in the third organic light emitting layer EML3 may be selected from, for example, a metal complex or an organometallic complex such as (4,6-F2ppy)2Irpic. However, the materials included in the organic light emitting layer EML are only examples, and the disclosure is not limited thereto.

The common electron transporting layer mETL may be disposed on the light emitting layer EL. The common electron transporting layer mETL may be a common layer disposed to overlap the first to third emission areas EA1, EA2, and EA3 and the non-emission area NLA. In other words, the common electron transporting layers mETL disposed to overlap the first to third emission areas EA1, EA2, and EA3 may extend from each other. The common electron transporting layer mETL may cover an underlying structure along the underlying structure. The common electron transporting layer mETL may be in contact with and cover both side surfaces of the first to third light emitting layers EL1, EL2, and EL3 facing the non-emission area NLA, upper surfaces of the first to third light emitting layers EL1, EL2, and EL3 facing the common electron transporting layer mETL, and upper surfaces of the first portions 151a of the inorganic pixel defining layer 151.

The common electron transporting layer mETL may serve to inject and transport electrons transferred from the common electrode CE into the light emitting layer EL. As an example, the common electron transporting layer mETL may include tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), and mixtures thereof, lanthanide metals such as LiF, lithium quinolate (LiQ), Li₂O, BaO, NaCl, CsF, and Yb, halogenated metals such as RbCl and RbI, or the like, but is not limited thereto.

The common electrode CE may be disposed on the common electron transporting layer mETL. The common electrode CE according to an embodiment may be a common layer disposed to overlap the first to third emission areas EA1, EA2, and EA3 and the non-emission area NLA.

The common electrode CE may include a transparent conductive material to emit the light generated from the light emitting layer EL. The common electrode CE may receive a common voltage or a low potential voltage. In case that the anode electrode AE receives a voltage corresponding to the data voltage and the common electrode CE receives the low potential voltage, holes and electrons may move to the organic light emitting layer EML through the hole transporting layer HTL and the hole injection layer HIL, and the common electron transporting layer mETL, respectively, and may combine with each other in the organic light emitting layer EML to emit the light. For example, a potential difference is formed between the anode electrode AE and the common electrode CE, such that the light emitting layer EL may emit the light.

In an embodiment, the common electrode CE may include a material layer having a small work function, such as Li, Ca, LiF/Ca, LiF/Al, Al, Mg, Ag, Pt, Pd, Ni, Au, Nd, Ir, Cr, BaF, Ba, or compounds or mixtures thereof (for example, a mixture of Ag and Mg, etc.). The common electrode CE may further include a transparent metal oxide layer disposed on the material layer having the small work function.

The capping layer 159 may be disposed on the common electrode CE. The capping layer 159 may be a common layer disposed to overlap the first to third emission areas EA1, EA2, and EA3 and the non-emission area NLA. The capping layer 159 may prevent a plurality of light emitting elements ED from being damaged by external air. As an example, the capping layer 159 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The thin film encapsulation layer 170 may be positioned on the capping layer 159. The thin film encapsulation layer 170 may be disposed in portions overlapping the first to third emission areas EA1, EA2, and EA3 and the non-emission area NLA.

The thin film encapsulation layer 170 may include at least one inorganic film to prevent oxygen or moisture from permeating into the display element layer 150. The thin film encapsulation layer 170 may include at least one organic film to protect the display element layer 150 from foreign substances such as dust. The thin film encapsulation layer 170 may include a first encapsulation layer 171, a second encapsulation layer 173, and a third encapsulation layer 175 that may be sequentially stacked. The first encapsulation layer 171 and the third encapsulation layer 175 may be inorganic encapsulation layers, and the second encapsulation layer 173 disposed between the first encapsulation layer 171 and the third encapsulation layer 175 may be an organic encapsulation layer.

Each of the first encapsulation layer 171 and the third encapsulation layer 175 may include one or more inorganic insulating materials. The inorganic insulating material may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may include a polymer-based material. The polymer-based material may include a silicone-based resin, an acrylic resin, an epoxy-based resin, and mixtures thereof. For example, the second encapsulation layer 173 may include an acrylic resin such as polymethyl methacrylate or polyacrylic acid. The second encapsulation layer 173 may be formed by curing a monomer or applying a polymer.

The touch sensor layer 180 may be disposed on the thin film encapsulation layer 170. The touch sensor layer 180 may include a touch buffer layer 181, a touch insulating layer 183, touch electrodes TE, and a touch protection layer 185.

The touch buffer layer 181 may be disposed on the thin film encapsulation layer 170. The touch buffer layer 181 may have insulating and optical functions. The touch buffer layer 181 may include at least one inorganic film. Optionally, the touch buffer layer 181 may be omitted.

Although not illustrated in the drawings, a connection electrode electrically connecting the touch electrodes to each other may be disposed on the touch buffer layer 181. The connection electrode may be formed as a single layer made of molybdenum (Mo), titanium (Ti), copper (Cu), aluminum (Al), or ITO or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The touch insulating layer 183 may cover the touch buffer layer 181. The touch insulating layer 183 may have insulating and optical functions. For example, the touch insulating layer 183 may be an inorganic film including at least one of a silicon nitride layer, a silicon oxynitride layer, a silicon oxide layer, a titanium oxide layer, and an aluminum oxide layer.

Some of the touch electrodes TE may be disposed on the touch insulating layer 183. Each of the touch electrodes TE may not overlap the first to third emission areas EA1, EA2, and EA3, and may be positioned in the non-emission area NLA. Each of the touch electrodes TE may be formed as a single layer made of molybdenum (Mo), titanium (Ti), copper (Cu), aluminum (Al), or ITO or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The touch protection layer 185 may cover the touch electrodes TE and the touch insulating layer 183. The touch protection layer 185 may have insulating and optical functions. The touch protection layer 185 may be made of the example material in the touch insulation layer 183.

A light blocking layer BM may be disposed on the touch sensor layer 180. The light blocking layer BM may be disposed to overlap the inorganic pixel defining layer 151 in a portion overlapping the non-emission area NLA.

The light blocking layer BM may include a light absorbing material. For example, the light blocking layer BM may include an inorganic black pigment or an organic black pigment. The inorganic black pigment may be carbon black, and the organic black pigment may include at least one of Lactam Black, Perylene Black, and Aniline Black, but the disclosure is not limited thereto. The light blocking layer BM may prevent color mixing due to permeation of visible light between the first to third emission areas EA1, EA2, and EA3 to improve a color gamut of the display device 10.

The color filter layer 190 may be disposed on each of the touch protection layer 185 and the light blocking layer BM so as to overlap the first to third emission areas EA1, EA2, and EA3. The color filter layer 190 may include a first color filter 191, a second color filter 193, and a third color filter 195 disposed to each correspond to the first to third emission areas EA1, EA2, and EA3. The respective color filters 191, 193, and 195 respectively overlapping the first to third emission areas EA1, EA2, and EA3 may include colorants such as dyes or pigments absorbing light of wavelength bands other than light of a given wavelength band, and may be disposed to correspond to colors of the light emitting from the first to third emission areas EA1, EA2, and EA3. For example, the first color filter 191 may be a red color filter disposed to overlap the first emission area EA1 and transmitting only the red light, which is the light of the first color. The second color filter 193 may be a green color filter disposed to overlap the second emission area EA2 and transmitting only the green light, which is the light of the second color, and the third color filter 195 may be a blue color filter disposed to overlap the third emission area EA3 and transmitting only the blue light, which is the light of the third color. The disclosure is not limited thereto.

The color filter layer 190 may also be omitted according to embodiments.

An overcoat layer OC may be disposed on the color filter layer 190 to planarize an upper end of the color filter layer 190. The overcoat layer OC may be a colorless light transmitting layer that does not have a color of a visible light band. For example, the overcoat layer OC may include a colorless light transmitting organic material such as an acrylic resin.

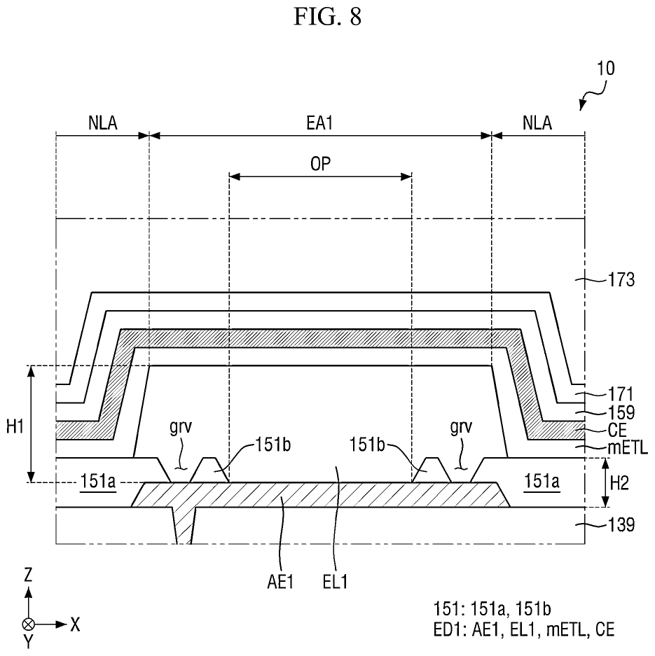

FIG. 8 is an enlarged cross-sectional view of a first emission area EA1 in FIG. 6.

Referring to FIG. 8, the inorganic pixel defining layer 151 according to an embodiment may define the opening OP, and the opening OP may overlap the first emission area EA1. A width of the opening OP in the first direction (X-axis direction) may be smaller than a width of the first emission area EA1 in the first direction (X-axis direction), and the opening OP may be positioned inside the first emission area EA1.

The first portion 151a of the inorganic pixel defining layer 151 included in an embodiment may be positioned on the second via layer 139 in a portion overlapping the non-emission area NLA, and may be disposed to cover a portion of the first anode electrode AE1 in a portion overlapping the first emission area EA1. The second portion 151b according to an embodiment may be disposed on the first anode electrode AE1 so as to be in contact with the first anode electrode AE1 in the portion overlapping the first emission area EA1.

In an embodiment, a groove grv may be formed between the first portion 151a and the second portion 151b of the inorganic pixel defining layer 151. In other words, the first portion 151a and the second portion 151b may be spaced apart from each other with the groove grv therebetween. The groove grv formed between the first portion 151a and the second portion 151b may be a portion recessed toward the anode electrode AE. The first portion 151a and the second portion 151b of the inorganic pixel defining layer 151 included in an embodiment may be integral with each other, and be formed to be spaced apart from each other with the groove grv therebetween by a subsequent etching process. Accordingly, the first portion 151a and the second portion 151b according to an embodiment may include a same material. According to embodiments, the groove grv may be referred to as a hole, a recessed portion, a trench portion, a depressed portion, or the like within the spirit and the scope of the disclosure.

The first light emitting layer EL1 may be disposed on a plurality of inorganic pixel defining layers 151 neighboring to each other and the first anode electrode AE1. The first light emitting layer EL1 may be formed to cover the first portion 151a and the second portion 151b of the inorganic pixel defining layer 151, and may be formed to fill the groove grv formed between the first portion 151a and the second portion 151b. The light emitting layer EL according to an embodiment is formed to fill the groove grv included in the inorganic pixel defining layer 151, such that an adhesion area between the light emitting layer EL and an underlying structure may be increased. For example, the light emitting layer EL according to an embodiment may increase adhesive strength with the underlying structure. As a result, the display device 10 according to an embodiment may solve a detachment defect of the light emitting layer EL caused by an etching process and a cleaning process of a fabricating process. This may assist in forming the common electron transporting layer mETL and the common electrode CE without a disconnection defect in a subsequent process.

The light emitting layer EL according to an embodiment may completely fill the groove grv, but is not limited thereto.

In an embodiment, a height H2 of the inorganic pixel defining layer 151 in the third direction (Z-axis direction) may be smaller than a height H1 of the first light emitting layer EL1. As an example, the height H2 of the inorganic pixel defining layer 151 may be less than half the height H1 of the first light emitting layer EL1.

Referring to FIGS. 6 and 8, the common electron transporting layer mETL and the common electrode CE according to an embodiment may be entirely formed to overlap the first to third emission areas EA1, EA2, and EA3 and the non-emission area NLA, and may cover an underlying structure along a profile of the underlying structure. In other words, the common electron transporting layer mETL according to an embodiment may be positioned between the first portion 151a of the inorganic pixel defining layer 151 and the common electrodes CE in the third direction (Z-axis direction) in a portion overlapping the non-emission area NLA, and may be in contact with the first portion 151a of the inorganic pixel defining layer 151 and the common electrode CE in the third direction (Z-axis direction) in the portion overlapping the non-emission area NLA.

As described above, the light emitting layer EL according to an embodiment may be formed without the mask in the fabricating process, and thus, the display device 10 according to an embodiment may solve a mask shadow defect. The mask shadow defect may refer to a phenomenon in which a portion of a material of the light emitting layer EL is formed in the portion overlapping the non-emission area NLA.

The capping layer 159, the first encapsulation layer 171, and the second encapsulation layer 173 may be sequentially stacked on the common electrode CE. A common description will be omitted. For convenience of explanation, the first anode electrode AE1 and the first light emitting layer EL1 disposed to overlap the first emission area EA1 have been illustrated and described, but the first to third anode electrodes AE1, AE2, and AE3 and the first to third light emitting layers EL1, EL2, and EL3 may have the same structure and characteristics.

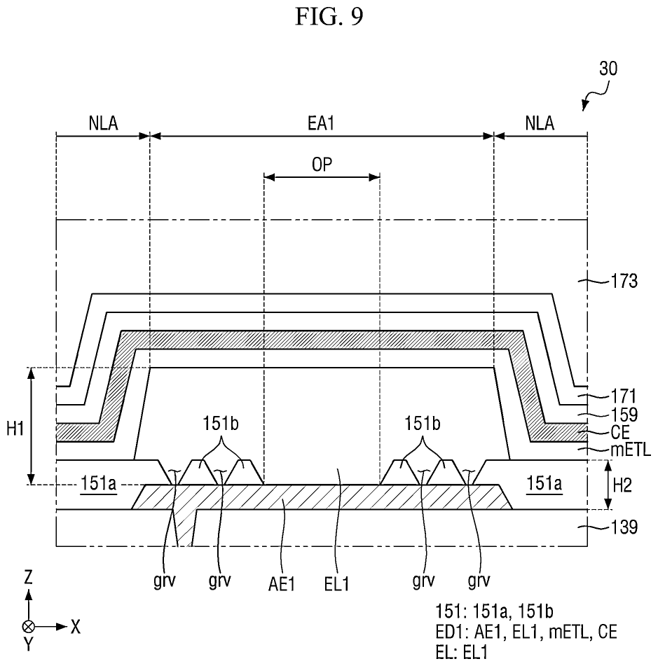

FIG. 9 is an enlarged cross-sectional view of a first emission area EA1 according to an embodiment.

Referring to FIG. 9, a display device 30 according to an embodiment is different from the display device 10 according to an embodiment in that a second portion 151b of an inorganic pixel defining layer 151 may include a plurality of grooves grv. The inorganic pixel defining layer 151 according to an embodiment may include first portions 151a and second portions 151b that are integral with each other in a fabricating process and are formed to overlap the non-emission area NLA and the first to third emissions EA1, EA2, and EA3, respectively, through a photolithography process. A plurality of second portions 151b may be formed to overlap each of the first to third emission areas EA1, EA2, and EA3, and the grooves grv may be formed between the plurality of second portions 151b neighboring to each other. It has been illustrated in FIG. 9 that the number of second portions 151b is two, but the disclosure is not limited thereto. In an embodiment, a plurality of second portions 151b such as two or more second portions 151b may be formed, and the grooves grv may be respectively formed between the plurality of second portions 151b neighboring to each other.

A first light emitting layer EL1 according to an embodiment may be formed to fill the plurality of grooves grv included in the inorganic pixel defining layer 151 according to an embodiment. Accordingly, an adhesion area and adhesive strength between the first light emitting layer EL1 and an underlying structure according to an embodiment may be greater than those of the display device 10 according to an embodiment. Accordingly, the display device 30 according to an embodiment may solve a detachment defect of the light emitting layer EL caused in the fabricating process. This may assist in forming the common electron transporting layer mETL and the common electrode CE without a disconnection defect in a subsequent process.

A height H2 of the inorganic pixel defining layer 151 according to an embodiment in the third direction (Z-axis direction) may be smaller than a height H1 of the first light emitting layer EL1. As an example, the height H2 of the inorganic pixel defining layer 151 may be less than half the height H1 of the first light emitting layer EL1. An overlapping description will be omitted.

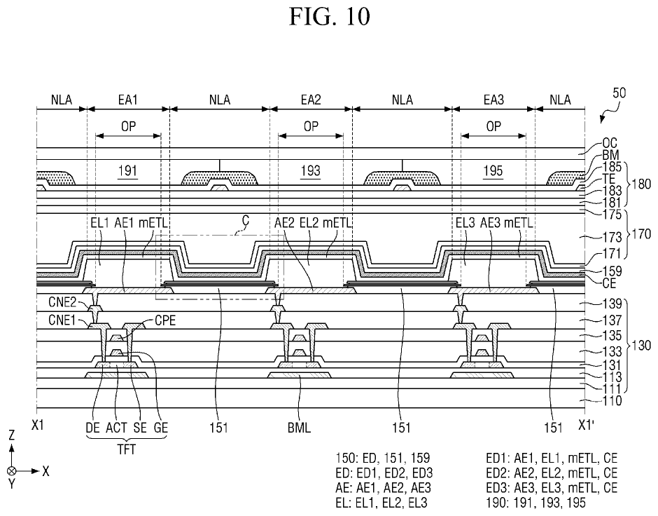

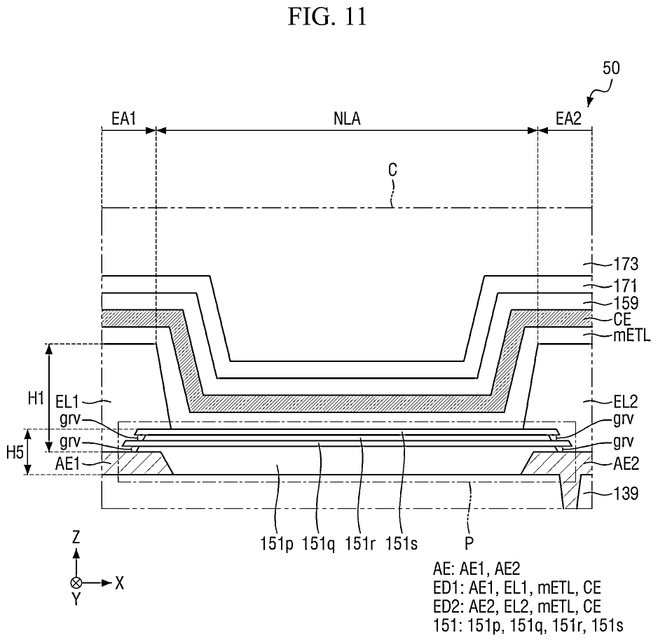

FIG. 10 is a schematic cross-sectional view of a display area taken along line X1-X1′ of FIG. 5 according to an embodiment. FIG. 11 is an enlarged cross-sectional view of area ‘C’ in FIG. 10.

Referring to FIGS. 10 and 11, a display device 50 according to an embodiment may be different from the display device 10 according to an embodiment and the display device 30 according to an embodiment in a shape of an inorganic pixel defining layer 151 in a portion overlapping the non-emission area NLA. By way of example, the inorganic pixel defining layer 151 of each of the display device 10 and the display device 30 may increase an adhesion area between the light emitting layer EL and the underlying structure by including the groove grv in a direction parallel to the substrate 110, for example, in the first direction (X-axis direction), while the display device 50 according to an embodiment may increase an adhesion area between the light emitting layer EL and the inorganic pixel defining layer 151 by including a plurality of grooves grv in a direction perpendicular to the substrate 110, for example, in the third direction (Z-axis direction). The inorganic pixel defining layer 151 included in the display device 50 according to an embodiment may be formed in a multilayer structure including different materials. The groove grv included in the inorganic pixel defining layer 151 according to an embodiment may be referred to as an undercut according to embodiments.

The inorganic pixel defining layer 151 according to an embodiment may be positioned on the second via layer 139 and a plurality of anode electrodes AE neighboring to each other. The inorganic pixel defining layer 151 according to an embodiment may allow the first to third anode electrodes AE1, AE2, and AE3 from being spaced apart and insulated from each other.

In an embodiment, the inorganic pixel defining layer 151 according to an embodiment may include a first portion 151p, a second portion 151q, a third portion 151r, and a fourth portion 151s that are stacked in the third direction (Z-axis direction). The first portion 151p and the third portion 151r of the inorganic pixel defining layer 151 may include the same inorganic material, and the second portion 151q and the fourth portion 151s of the inorganic pixel defining layer 151 may also include the same material. However, the first portion 151p of the inorganic pixel defining layer 151 may include a different inorganic material from the second portion 151q and the fourth portion 151s, and the second portion 151q of the inorganic pixel defining layer 151 may include a different inorganic material different from the first portion 151p and the third portion 151r.

In an embodiment, a height H5 of the inorganic pixel defining layer 151 according to an embodiment in the third direction (Z-axis direction) may be smaller than the height H1 of the first to third light emitting layers EL1, EL2, and EL3. As an example, the height H5 of the inorganic pixel defining layer 151 according to an embodiment may be less than half the height H1 of the first to third light emitting layers EL1, EL2, and EL3.

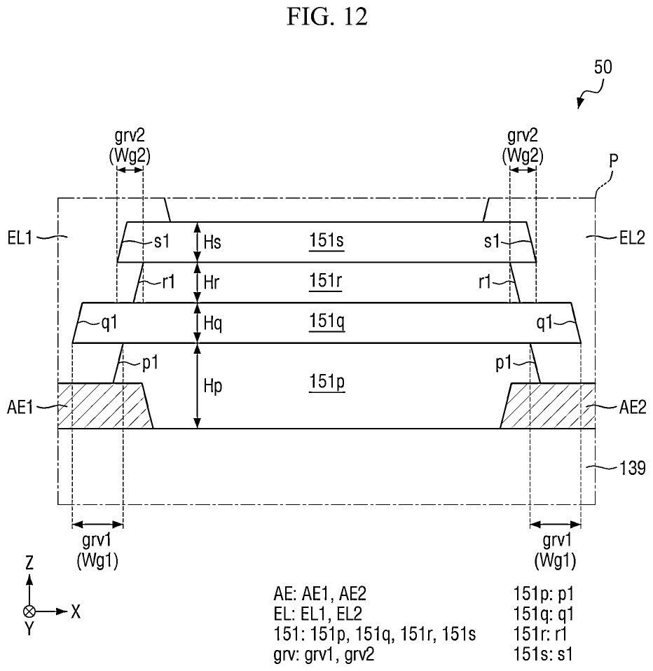

FIG. 12 is an enlarged cross-sectional view of area ‘P’ in FIG. 11.

Referring to FIG. 12 in addition to FIGS. 10 and 11, the inorganic pixel defining layer 151 according to an embodiment may be formed using a dry etching process in a fabricating process. The inorganic pixel defining layer 151 according to an embodiment may include the different materials, and accordingly, may have different etch selectivities with respect to an etching solution. This will be described in detail later.

The first portion 151p included in the inorganic pixel defining layer 151 according to an embodiment may be positioned on a plurality of anode electrodes AE neighboring to each other and the second via layer 139. The first portion 151p according to an embodiment may cover portions of the plurality of anode electrodes AE neighboring to each other. The first portion 151p according to an embodiment may allow the plurality of anode electrodes AE neighboring to each other to be spaced apart and insulated from each other.

The first portion 151p according to an embodiment may include an inorganic material, for example, either silicon nitride or silicon oxynitride. As described above, the first portion 151p according to an embodiment may include the same inorganic material as the third portion 151r, and may include a different inorganic material from the second portion 151q and the fourth portion 151s.

In an embodiment, a height Hp of the first portion 151p in the third direction (Z-axis direction) may be greater than heights of the second portion 151q, the third portion 151r, and the fourth portion 151s according to an embodiment. The height Hp of the first portion 151p in the third direction (Z-axis direction) may be greater than a height of the plurality of anode electrodes AE. As an example, the height Hp of the first portion 151p may be about 0.1 μm, but is not limited thereto.

In an embodiment, the second portion 151q according to an embodiment may be positioned on the first portion 151p so as to be in contact with the first portion 151p. The second portion 151q according to an embodiment may include an inorganic material, for example, silicon oxide. As described above, the second portion 151q may include the same inorganic material as the fourth portion 151s, and may include a different inorganic material from the first portion 151p and the third portion 151r.

In an embodiment, a height Hq of the second portion 151q in the third direction (Z-axis direction) may be smaller than the height Hp of the first portion 151p according to an embodiment. As an example, the height Hq of the second portion 151q may be about 0.02 μm, but is not limited thereto.

In a fabricating process of the inorganic pixel defining layer 151 according to an embodiment, an etch selectivity of the second portion 151q may be smaller than an etch selectivity of the first portion 151p. This may mean that an etch rate of the first portion 151p is higher than an etch rate of the second portion 151q. Accordingly, both side surfaces q1 of the second portion 151q facing the first to third light emitting layers EL1, EL2, and EL3 may protrude toward each of the first to third emission areas EA1, EA2, and EA3 more than both side surfaces p1 of the first portion 151p. This may mean that both side surfaces p1 of the first portion 151p facing the first to third light emitting layers EL1, EL2, and EL3 are recessed toward the non-emission area NLA more than both side surfaces q1 of the second portion 151q. As a result, a groove grv1 may be formed between the first portion 151p and the second portion 151q according to an embodiment in a portion overlapping each of the first to third emission areas EA1, EA2, and EA3.

In other words, in the portion overlapping each of the first to third emission areas EA1, EA2, and EA3, the second portion 151q according to an embodiment may have a protrusion part protruding more than the first portion 151p in the first direction (X-axis direction), and an undercut may be formed between the protrusion part of the second portion 151q and the side surface p1 of the first portion 151p. The second portion 151q according to an embodiment may be spaced apart from the anode electrode AE in the third direction (Z-axis direction) by the groove grv1 formed between the first portion 151p and the second portion 151q according to an embodiment.

The third portion 151r according to an embodiment may be positioned on the second portion 151q so as to be in contact with the second portion 151q. The third portion 151r may include an inorganic material, for example, either silicon nitride or silicon oxynitride. As described above, the third portion 151r according to an embodiment may include the same inorganic material as the first portion 151p, and may include a different inorganic material from the second portion 151q and the fourth portion 151s.

In an embodiment, a height Hr of the third portion 151r in the third direction (Z-axis direction) may be smaller than the height Hp of the first portion 151p according to an embodiment. As an example, the height Hr of the third portion 151r may be about 0.02 μm, but is not limited thereto.

The fourth portion 151s according to an embodiment may be positioned on third portion 151r so as to be in contact with the third portion 151r. The fourth portion 151s may include an inorganic material, for example, silicon oxide. As described above, the fourth portion 151s may include the same inorganic material as the second portion 151q, and may include a different inorganic material from the first portion 151p and the third portion 151r.

In an embodiment, a height Hs of the fourth portion 151s in the third direction (Z-axis direction) may be smaller than the height Hp of the first portion 151p according to an embodiment. As an example, the height Hs of the fourth portion 151s may be about 0.02 μm, but is not limited thereto.

In the fabricating process of the inorganic pixel defining layer 151 according to an embodiment, an etch selectivity of the fourth portion 151s may be smaller than an etch selectivity of the third portion 151r. This may mean that an etch rate of the third portion 151r is higher than an etch rate of the fourth portion 151s. Accordingly, both side surfaces s1 of the fourth portion 151s facing the first to third light emitting layers EL1, EL2, and EL3 may protrude toward each of the first to third emission areas EA1, EA2, and EA3 more than both side surfaces r1 of the third portion 151r. This may mean that both side surfaces r1 of the third portion 151r facing the first to third light emitting layers EL1, EL2, and EL3 are recessed toward the non-emission area NLA more than both side surfaces s1 of the fourth portion 151s. As a result, a groove grv2 may be formed between the third portion 151r and the fourth portion 151s according to an embodiment in the portion overlapping each of the first to third emission areas EA1, EA2, and EA3.

In other words, in the portion overlapping each of the first to third emission areas EA1, EA2, and EA3, the fourth portion 151s according to an embodiment may have a protrusion part protruding more than the third portion 151r in the first direction (X-axis direction), and an undercut may be formed between the protrusion part of the fourth portion 151s and the side surface r1 of the third portion 151r.

In an embodiment, the groove grv1 formed between the first portion 151p and the second portion 151q may have a width Wg1 in the first direction (X-axis direction), and the width Wg1 may be about 0.05 μm or less. The groove grv2 formed between the third portion 151r and the fourth portion 151s may have a width Wg2 in the first direction (X-axis direction), and the width Wg2 may be about 0.05 μm or less. The width Wg1 of the groove grv1 formed between the first portion 151p and the second portion 151q and the width Wg2 of the groove grv2 formed between the third portion 151r and the fourth portion 151s may be the same as each other or be different from each other.

Referring to FIGS. 10 to 12, the light emitting layer EL according to an embodiment may be formed to fill a profile formed by the first to fourth portions 151p, 151q, 151r, and 151s of the inorganic pixel defining layer 151 in the portion overlapping each of the first to third emission areas EA1, EA2, and EA3. By way of example, the first light emitting layer EL1 according to an embodiment may fill the groove grv1 formed between the first portion 151p and the second portion 151q of the inorganic pixel defining layer 151 and the groove grv2 formed between the third portion 151r and the four portion 151s of the inorganic pixel defining layer 151. In other words, the first light emitting layer EL1 according to an embodiment may fill the undercut formed between the first portion 151p and the second portion 151q and the undercut formed between the third portion 151r and the fourth portion 151s.

For example, the first to third light emitting layers EL1, EL2, and EL3 according to an embodiment may be formed to fill the plurality of grooves grv. As a result, adhesion areas and adhesive strength between the first to third light emitting layers EL1, EL2, and EL3 and the inorganic pixel defining layer 151 may be increased. Accordingly, detachment defects of the first to third light emitting layers EL1, EL2, and EL3 in a fabricating process of the display device 50 may be solved, which may assist in forming the common electron transporting layer mETL and the common electrode CE without a disconnection defect in a subsequent process.

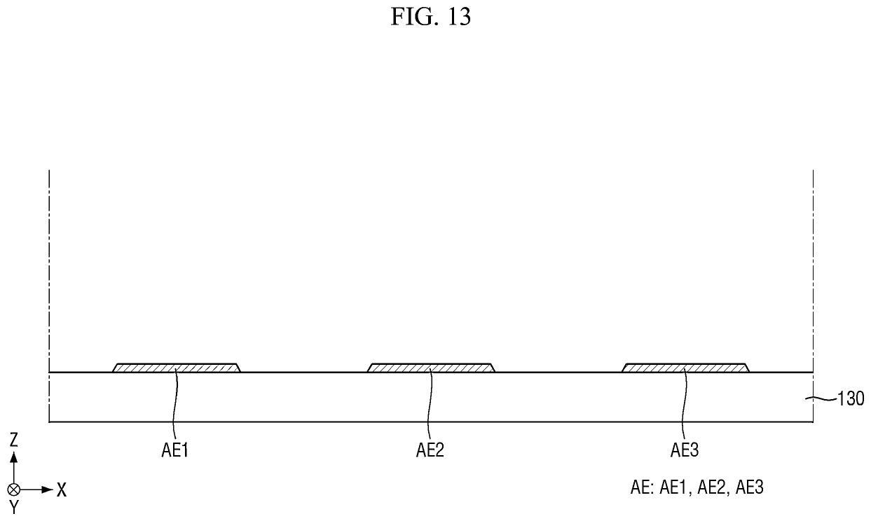

FIGS. 13 to 22 are schematic cross-sectional views illustrating a method of fabricating a display element layer in FIG. 6. By way of example, in FIGS. 13 to 22, the formation order of the inorganic pixel defining layer 151 overlapping the non-emission area NLA and the plurality of light emitting elements ED overlapping the first to third emission areas EA1, EA2, and EA3 are schematically illustrated. Hereinafter, a fabricating process of the display device 10 will be described in relation to the formation order of each layer.

Referring to FIG. 13, a plurality of anode electrodes AE are formed on the thin film transistor layer 130. The plurality of anode electrodes AE may include first to third anode electrodes AE1, AE2, and AE3, and the first to third anode electrodes AE1, AE2, and AE3 may later be disposed to overlap the first to third emission areas EA1, EA2, and EA3, respectively. Although not illustrated in FIG. 13, the thin film transistor layer 130 may be disposed on the substrate 110, and a structure of the thin film transistor layer 130 is the same as that described above with reference to FIG. 6. A detailed description thereof will be omitted.

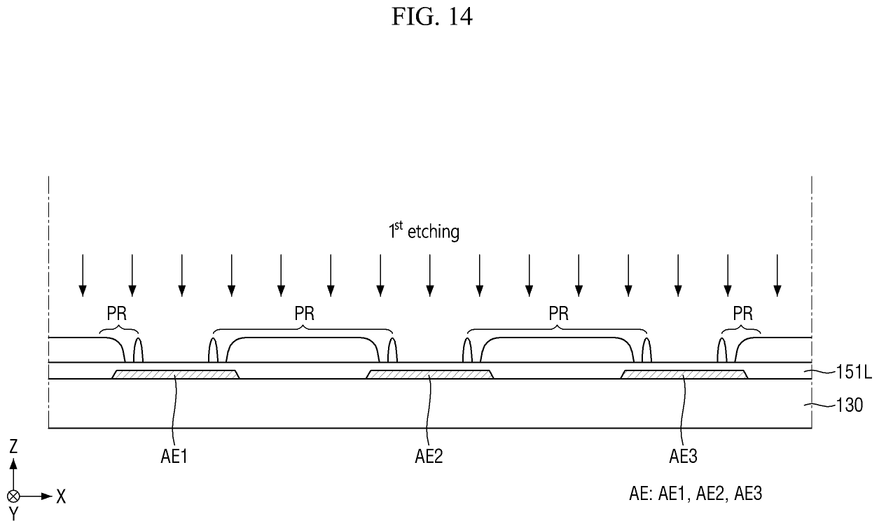

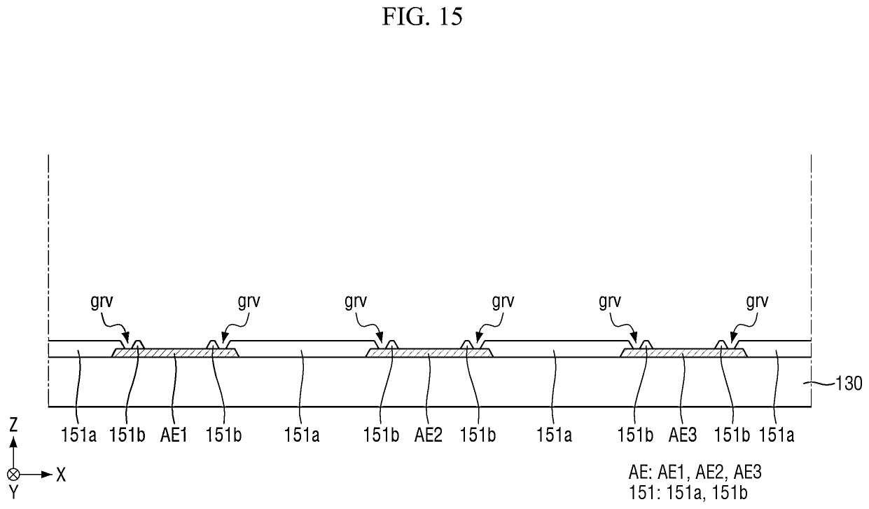

Subsequently, referring to FIGS. 14 and 15, a pixel defining material layer 151L is entirely formed the thin film transistor layer 130 and the plurality of anode electrodes AE. A photoresist PR is formed on the pixel defining material layer 151L, and a first etching process (1^{st} etching) of etching portions of the pixel defining material layer 151L using the photoresist PR as a mask is performed. As an example, the first etching process (1^{st} etching) may be a dry etching process. Through the process, the first portions 151a and the second portions 151b of the inorganic pixel defining layer 151 illustrated in FIG. 15 may be formed, and the grooves grv may be formed between the first portions 151a and the second portions 151b of the inorganic pixel defining layer 151. The groove grv according to an embodiment may refer to a portion recessed toward the anode electrode AE, and may be referred to as a hole, a recessed portion, a trench portion, or a depressed portion, or the like, according to embodiments.

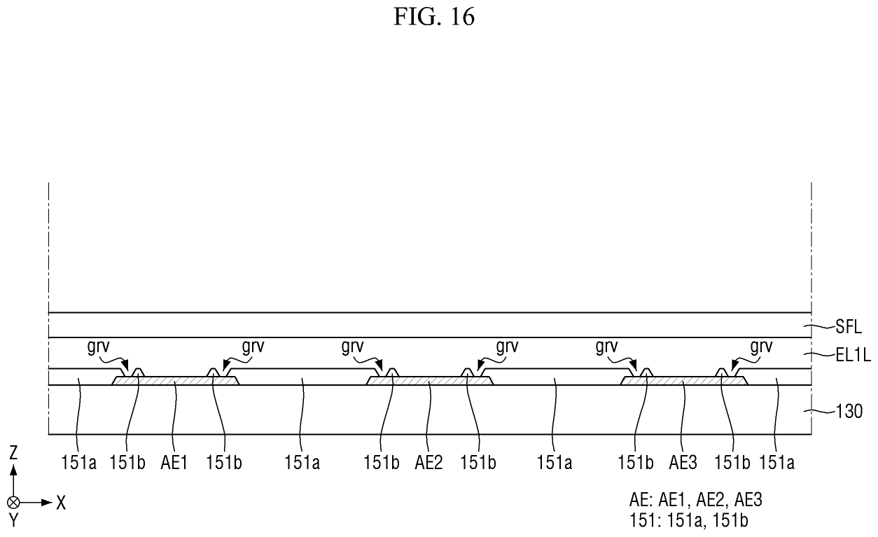

Subsequently, referring to FIG. 16, a first light emitting material layer EL1L may be formed to entirely cover the plurality of anode electrodes AE and the inorganic pixel defining layer 151. The first light emitting material layer EL1L may include the hole injection layer HIL, the hole transporting layer HTL, and the first organic light emitting layer EML1 illustrated in FIG. 7. A sacrificial layer SFL may be disposed on the first light emitting material layer EL1L. The sacrificial layer SFL may protect the first light emitting material layer EL1L from an etching solution in case that it is subjected to a photolithography process in a subsequent process. The sacrificial layer SFL may be formed directly on the first light emitting material layer EL1L, and may include a metal material. As an example, the sacrificial layer SFL may include aluminum (Al), silver (Ag), and the like, but is not limited thereto. In the process, the first light emitting material layer EL1L may be formed to fill the grooves grv included in the inorganic pixel defining layer 151. The first light emitting material layer EL1L according to an embodiment may increase an adhesion area and adhesive strength with an underlying structure by filling the grooves grv included in the inorganic pixel defining layer 151.

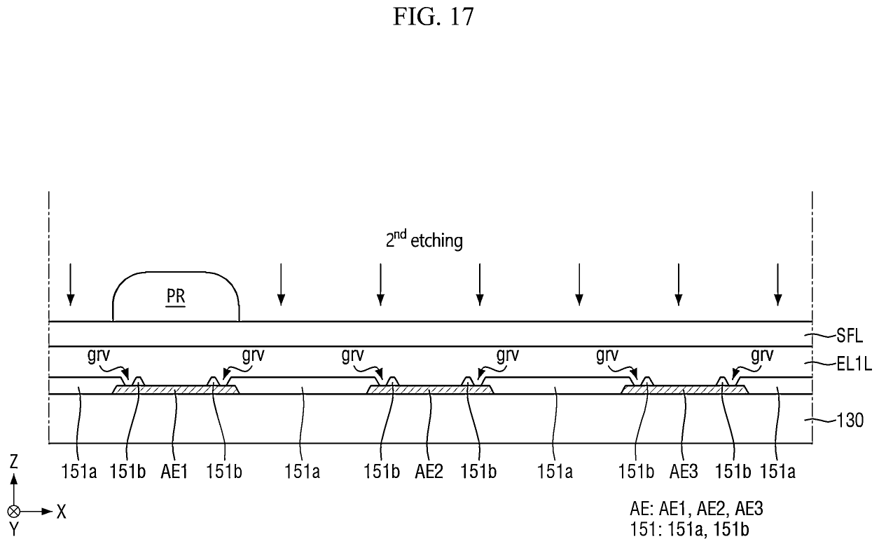

Referring to FIG. 17, a photoresist PR is formed on the sacrificial layer SFL overlapping the first anode electrode AE1, and a second etching process (2^{nd} etching) of etching portions of the sacrificial layer SFL and the first light emitting material layer EL1L using the photoresist PR as a mask is performed. In the process, the first light emitting material layer EL1L may be exposed to an etching process and a cleaning process. Since the first light emitting material layer EL1L according to an embodiment has a great adhesion area and high adhesive strength with the underlying structure due to the groove grv included in the inorganic pixel defining layer 151, even though the first light emitting material layer EL1L is subjected to the etching process and the cleaning process, a detachment defect of the first light emitting material layer EL1L may be solved.

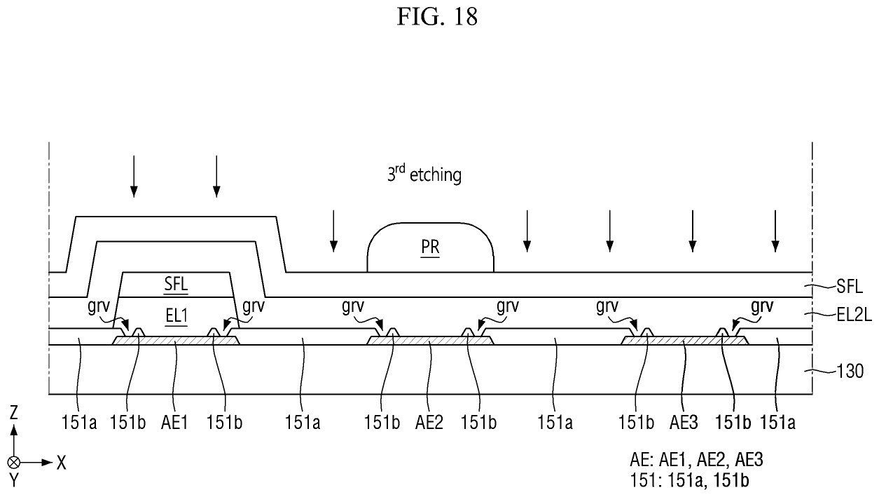

Through the process, the first light emitting layer EL1 and the sacrificial layer SFL disposed to overlap the first anode electrode AE1 as illustrated in FIG. 18 may be formed. As the second etching process, a dry etching process may be singly performed or a dry etching process and a wet etching process may be alternately performed.

Referring to FIG. 18, a second light emitting material layer EL2L and a sacrificial layer SFL are entirely formed on the sacrificial layer SFL positioned on the first light emitting layer EL1, the inorganic pixel defining layer 151, the second anode electrode AE2, and the third anode electrode AE3. In the process, the second light emitting material layer EL2L may cover the first light emitting layer EL1 along the first light emitting layer EL1. The second light emitting material layer EL2L may include the hole injection layer HIL, the hole transporting layer HTL, and the second organic light emitting layer EML2.

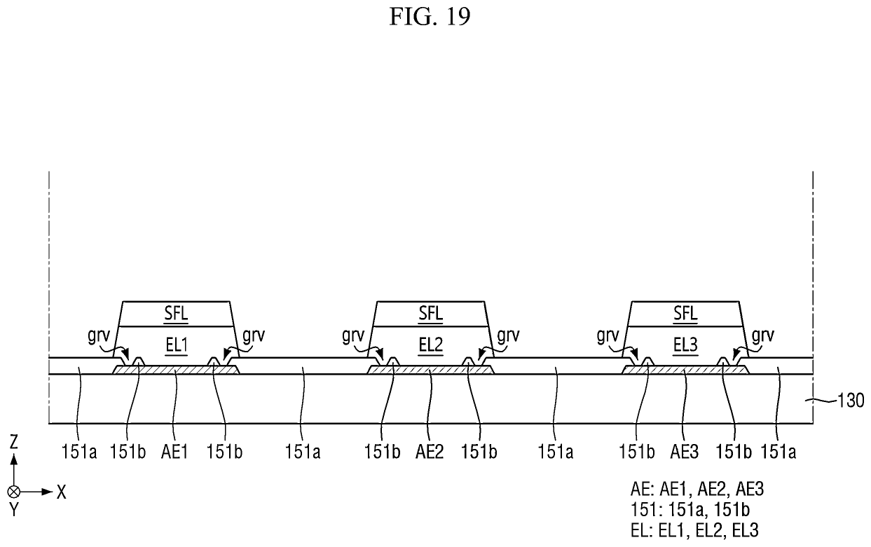

Subsequently, a photoresist PR is formed on the sacrificial layer SFL overlapping the second anode electrode AE2, and a third etching process (3^{rd} etching) of etching portions of the sacrificial layer SFL and the second light emitting material layer EL2L using the photoresist PR as a mask is performed. The third etching process may be the same process as the second etching process. In the process, the second light emitting layer EL2 and the sacrificial layer SFL disposed to overlap the second anode electrode AE2 as illustrated in FIG. 19 may be formed. In the process, the second light emitting material layer EL2L may be exposed to an etching process and a cleaning process. Since the second light emitting material layer EL2L according to an embodiment has a great adhesion area and high adhesive strength with an underlying structure due to the groove grv included in the inorganic pixel defining layer 151, even though the second light emitting material layer EL2L is subjected to the etching process and the cleaning process, a detachment defect of the second light emitting material layer EL2L may be solved.

The third light emitting layer EL3 and the sacrificial layer SFL overlapping the third anode electrode AE3 are formed by repeating the processes performed previously. For example, the third emitting layer EL3 and the sacrificial layer SFL overlapping the third light emitting layer EL3 may be formed by forming a third light emitting material layer on the sacrificial layer SFL overlapping the first light emitting layer EL1, the sacrificial layer SFL overlapping the second light emitting layer EL2, the inorganic pixel defining layer 151, and the third anode electrode AE3 and forming a photoresist PR on the sacrificial layer SFL overlapping the third anode electrode AE2. In the process, the third light emitting layer EL3 and the sacrificial layer SFL disposed to overlap the third anode electrode AE3 may be formed. Since the third light emitting material layer EL3L according to an embodiment has a great adhesion area and high adhesive strength with an underlying structure due to the groove grv included in the inorganic pixel defining layer 151, even though the third light emitting material layer EL3L is subjected to the etching process and the cleaning process, a detachment defect of the third light emitting material layer may be solved.

As illustrated in FIG. 19, the first light emitting layer EL1, the second light emitting layer EL2, and the third light emitting layer EL3 are formed by a photolithography process, and may thus have both side surfaces clear without mask shadow defects in the first direction (X-axis direction).

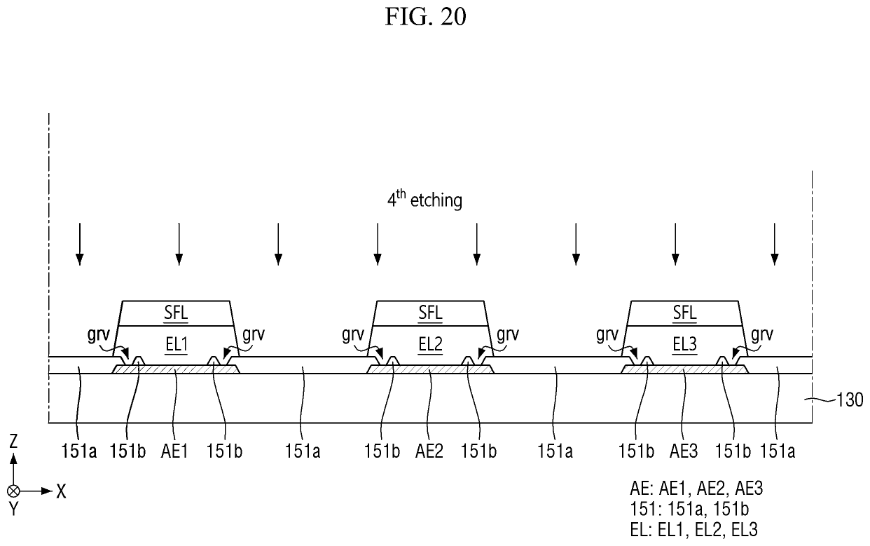

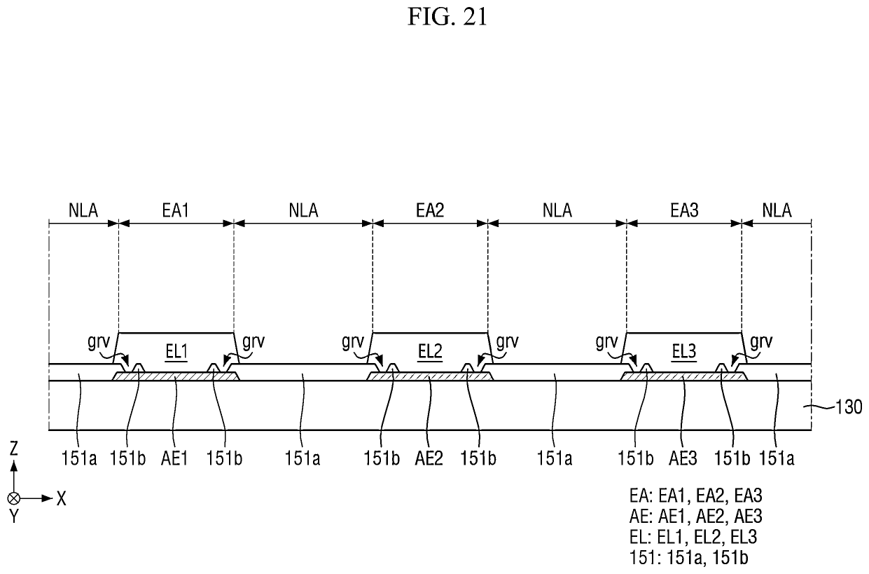

Referring to FIGS. 20 and 21, a fourth etching process (4^{th} etching) of removing the sacrificial layers SFL disposed to overlap the respective light emitting layers EL is performed. A wet etching process may be performed as the fourth etching process, and an acidic etching solution may be used as an etching solution. The etching solution may be limited to the acidic etching solution in the process in order to minimize damage to the plurality of light emitting layers EL. In the process, the sacrificial layers SFL may be removed, and the first light emitting layer EL1, the second light emitting layer EL2, and the third light emitting layer EL3 may be formed as illustrated in FIG. 21. In the process, the plurality of emission areas EA and the non-emission area NLA illustrated in FIG. 6 may be defined.

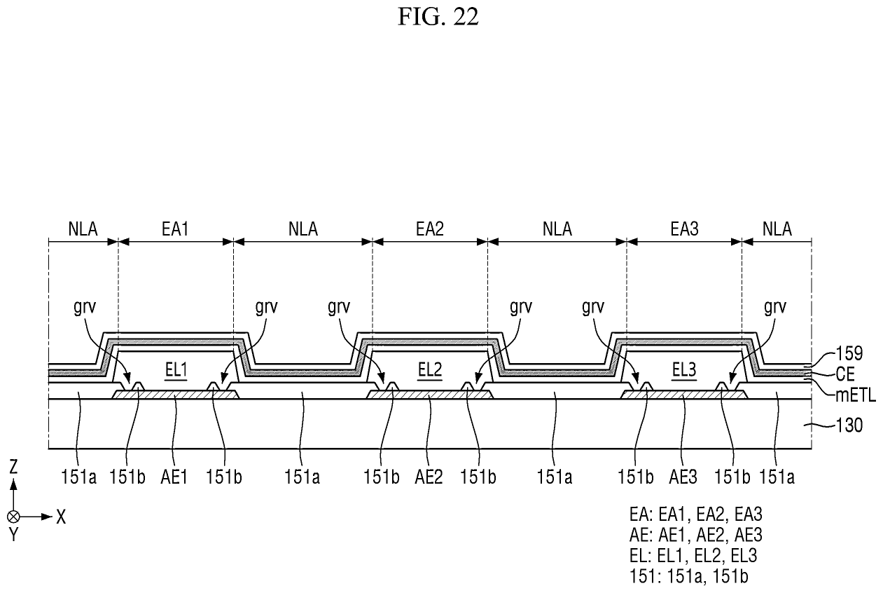

Finally, referring to FIG. 22, the common electron transporting layer mETL covering the first light emitting layer EL1, the second light emitting layer EL2, the third light emitting layer EL3, and the inorganic pixel defining layer 151 is entirely formed. The common electrode CE and the capping layer 159 are entirely formed on the common electron transporting layer mETL. Subsequently, although not illustrated in FIG. 22, the display device 10 may be fabricated by forming the first encapsulation layer 171, the second encapsulation layer 173, and the third encapsulation layer 175 to form the thin film encapsulation layer 170, and forming the touch sensor layer 180, the light blocking layer BM, the color filter layer 190, and the overcoat layer OC. The color filter layer 190 may be omitted according to embodiments.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure and as set forth in the following claims.

What is claimed is:

1. A display device comprising:
a substrate including an emission area and a non-emission area;
an anode electrode disposed on the emission area of the substrate;
a pixel defining layer disposed on the non-emission area of the substrate, the pixel defining layer defining an opening;
a light emitting layer disposed on the anode electrode;
a common electron layer disposed on the light emitting layer and the pixel defining layer; and
a common electrode disposed on the common electron layer, wherein
the pixel defining layer includes:
a first portion overlapping the non-emission area; and
a second portion overlapping the emission area and spaced apart from the first portion in a direction parallel to the substrate with a groove disposed between the first portion and the second portion, the groove being recessed toward the substrate,
the light emitting layer contacts the first portion and the second portion, and
the light emitting layer fills the groove between the first portion and the second portion.

2. The display device of claim 1, wherein a height of the pixel defining layer in a direction perpendicular to the substrate is less than about half the height of the light emitting layer.

3. The display device of claim 2, wherein the second portion is completely surrounded by the anode electrode and the light emitting layer.

4. The display device of claim 3, wherein
the pixel defining layer includes an inorganic material, and
the first portion and the second portion include a same material.

5. The display device of claim 4, wherein the opening is completely surrounded by the emission area in plan view.

6. The display device of claim 1, wherein the common electron layer is disposed between the pixel defining layer and the common electrode in a portion overlapping the non-emission area.

7. The display device of claim 6, wherein the common electron layer contacts the first portion and the common electrode in the portion overlapping the non-emission area.

8. The display device of claim 7, wherein a side surface of the light emitting layer facing the non-emission area contacts the common electron layer.

9. The display device of claim 1, wherein the light emitting layer is formed by photolithography.

10. The display device of claim 1, wherein the second portion includes a plurality of grooves recessed in a direction toward the substrate.

11. The display device of claim 10, wherein the light emitting layer fills the plurality of grooves included in the second portion.

12. A display device comprising:
a substrate including an emission area and a non-emission area;
an anode electrode disposed on the emission area of the substrate;
a pixel defining layer including a first portion disposed on the non-emission area of the substrate and a second portion including a different material from the first portion, the second portion disposed on the first portion;
a light emitting layer disposed on the anode electrode;
a common electron layer disposed on the light emitting layer and the pixel defining layer; and
a common electrode disposed on the common electron layer, wherein
a side surface of the second portion facing the emission area protrudes toward the emission area more than a side surface of the first portion facing the emission area, and
an undercut is formed between the second portion and the side surface of the first portion in a portion overlapping the emission area.

13. The display device of claim 12, wherein the light emitting layer fills the undercut formed between the second portion and the side surface of the first portion.

14. The display device of claim 13, wherein a height of the first portion in a direction perpendicular to the substrate is greater than a height of the second portion.

15. The display device of claim 12, wherein the pixel defining layer further includes:
a third portion disposed on the second portion, the third portion and the first portion including a same material; and
a fourth portion disposed on the third portion, the fourth portion and the second portion including a same material, and
a side surface of the fourth portion protrudes toward the emission area more than a side surface of the third portion in the portion overlapping the emission area.

16. The display device of claim 15, wherein
an undercut is formed between the fourth portion and the side surface of the third portion in the portion overlapping the emission area, and
the light emitting layer fills the undercut formed between the fourth portion and the side surface of the third portion.

17. The display device of claim 16, wherein a width of the undercut formed between the first portion and the second portion and a width of the undercut formed between the third portion and the fourth portion in a direction parallel to the substrate are about 0.05 μm or less.

18. The display device of claim 17, wherein
the first portion and the third portion include either silicon nitride or silicon oxynitride, and
the second portion and the fourth portion include silicon oxide.

19. The display device of claim 15, wherein
the common electron layer is disposed between the fourth portion and the common electrode in a portion overlapping the non-emission area, and
the common electron layer contacts the fourth portion and the common electrode in the portion overlapping the non-emission area.

20. A method of fabricating a display device, comprising:
providing a substrate including an emission area and a non-emission area;
forming a first anode electrode and a second anode electrode spaced apart from each other on the emission area of the substrate and forming a pixel defining material layer completely covering the first anode electrode, the second anode electrode, and the substrate;
forming a pixel defining layer including first portions and second portions spaced apart from the first portions with each of grooves disposed between the first portions and the second portions by removing portions of the pixel defining material layer except for portions overlapping the non-emission area and a portion of the emission area through etching, the grooves being recessed toward the substrate;
forming a first light emitting layer by forming a first light emitting material layer completely covering the first anode electrode, the second anode electrode, and the pixel defining layer, entirely forming a sacrificial layer on the first light emitting material layer, and removing the first light emitting material layer and the sacrificial layer in a remaining portion excluding a portion overlapping the first anode electrode through etching;
forming a second light emitting layer by forming a second light emitting material layer completely covering the first light emitting layer, the second anode electrode, and the pixel defining layer, entirely forming a sacrificial layer on the second light emitting material layer, and removing the second light emitting material layer and the sacrificial layer except for a portion overlapping the second anode electrode through etching; and
removing the sacrificial layer using wet etching, forming a common electron layer completely covering the first light emitting layer, the second light emitting layer, and the pixel defining layer, and entirely forming a common electrode on the common electron layer,
wherein in the forming of the first light emitting layer and the forming of the second emitting layer, the first light emitting layer and the second light emitting layer fill the grooves disposed between the first portions and the second portions of the pixel defining layer.
